(19) United States
(12) Patent Application Publication
(10) Pub. No.: US 2021/0343902 A1
(43) Pub. Date: Nov. 4, 2021

(54) OPTOELECTRONIC SEMICONDUCTOR COMPONENT HAVING A SAPPHIRE SUPPORT AND METHOD FOR THE PRODUCTION THEREOF

(71) Applicant: OSRAM Opto Semiconductors GmbH, Regensburg (DE)

(72) Inventors: Lutz Hoeppl, Alteglofsheim (DE); Attila Molnar, Gelugor, Penang (MY)

(73) Assignee: OSRAM Opto Semiconductors GmbH, Regensburg (DE)

(21) Appl. No.: 17/280,209

(22) PCT Filed: Sep. 27, 2018
(86) PCT No.: PCT/EP2019/075955

§ 371 Date: Mar. 26, 2021

(30) Foreign Application Priority Data
Sep. 27, 2018 (DE) 10 2018 123 931.9

(51) Int. Cl. H01L 33/14; H01L 33/22; H01L 33/00

(52) U.S. Cl. CPC H01L 33/14; H01L 33/0093; H01L 33/22

(57) ABSTRACT

An optoelectronic semiconductor component may include an optoelectronic semiconductor chip, a connecting material that contains amorphous aluminum oxide, and a sapphire support. The connecting material may be directly adjacent to the sapphire support. The optoelectronic semiconductor chip may be connected to the sapphire support by means of the connecting material containing aluminum oxide.

### CROSS-REFERENCE TO RELATED APPLICATIONS

The present application is a national stage entry according to 35 U.S.C. § 371 of PCT Application No. PCT/EP2019/075955 filed on Sep. 25, 2019; which claims priority to German Patent Application Serial Nos. 10 2018 123 931.9 filed on Sep. 27, 2018; all of which are incorporated herein by reference in their entirety and for all purposes.

### TECHNICAL FIELD

The disclosure relates to optoelectronic devices having optoelectronic semiconductor chips configured to emit electromagnetic radiation.

### BACKGROUND

A light emitting diode (LED) is a light emitting device based on semiconductor materials. For example, an LED includes a pn junction. When electrons and holes recombine with one another in the regions of the pn junction, due, for example, to a corresponding voltage being applied, electromagnetic radiation is generated.

In general, concepts are being sought which allow for the outcoupling efficiency of optoelectronic semiconductor devices to be improved.

The object of the present disclosure is to provide an improved optoelectronic semiconductor devices and an improved method for producing an optoelectronic semiconductor device.

According to embodiments, the object is achieved by the subject matter and the method of the independent patent claims. Advantageous further developments are defined in the dependent claims.

### SUMMARY

According to embodiments, an optoelectronic semiconductor device comprises an optoelectronic semiconductor chip, a connecting material containing amorphous aluminum oxide, and a sapphire support. The connecting material is directly adjacent to the sapphire support. The optoelectronic semiconductor chip is connected to the sapphire support via the connecting material containing amorphous aluminum oxide.

According to embodiments, the optoelectronic semiconductor chip comprises a first semiconductor layer of a first conductivity type and a second semiconductor layer of a second conductivity type, which form a semiconductor layer stack. The first semiconductor layer is arranged between the second semiconductor layer and the sapphire support.

As an example, a first main surface of the first semiconductor layer facing away from the second semiconductor layer may be roughened. A first main surface of the connecting material facing away from the first semiconductor layer may form a planar surface.

According to embodiments, the connecting material may be directly adjacent to the first semiconductor layer.

The optoelectronic semiconductor component may furthermore comprise a first current spreading layer which is connected to the first semiconductor layer in an electrically conductive manner. As an example, the first current spreading layer may be arranged on a side of the first semiconductor layer facing away from the second semiconductor layer. The first current spreading layer may be directly adjacent to the first semiconductor layer.

According to embodiments, a first main surface of the first semiconductor layer and a first main surface of the first current spreading layer facing away from the first semiconductor layer are roughened.

As an example, the first current spreading layer may consist of a transparent conductive material.

The optoelectronic semiconductor component may furthermore comprise a dielectric intermediate layer on a side of the first current spreading layer facing away from the first semiconductor layer.

As an example, a first main surface of the dielectric intermediate layer facing away from the first current spreading layer may be roughened. The connecting material may be arranged between the dielectric intermediate layer and the sapphire support.

The first current spreading layer may be formed over the entire surface area.

According to further embodiments, the first current spreading layer may be formed in a ring shape.

According to embodiments, a method for producing an optoelectronic semiconductor component comprises forming an optoelectronic semiconductor chip, forming a connecting material containing amorphous aluminum oxide over the optoelectronic semiconductor chip, and bringing a sapphire support in contact with the connecting material and connecting the optoelectronic semiconductor chip to the sapphire support via the connecting material.

As an example, forming the optoelectronic semiconductor chip may include forming a first semiconductor layer of a first conductivity type over a growth substrate and forming a second semiconductor layer of a second conductivity type over the first semiconductor layer.

The method may further include applying an intermediate support over the second semiconductor layer and removing the growth substrate, wherein the connecting material containing amorphous aluminum oxide and the sapphire support are applied to one side of the first semiconductor layer.

The method may furthermore comprise roughening a first main surface of the first semiconductor layer before applying the connecting material containing amorphous aluminum oxide.

According to embodiments, the method further comprises forming a first current spreading layer over the first semiconductor layer after the growth substrate has been removed.

### BRIEF DESCRIPTION OF THE DRAWINGS

The accompanying drawings serve to provide an understanding of non-limiting embodiments. The drawings illustrate nonlimiting embodiments and, together with the description, serve for explanation thereof. Further non-limiting embodiments and many of the intended advantages will become apparent directly from the following detailed description. The elements and structures shown in the drawings are not necessarily shown to scale relative to each other. Like reference numerals refer to like or corresponding elements and structures.

FIG. 1A shows a schematic cross-sectional view of an optoelectronic semiconductor component according to embodiments.

FIG. 1B shows a schematic vertical cross-sectional view of an optoelectronic semiconductor component according to further embodiments.

FIGS. 2A and 2B show schematic cross-sectional views of an optoelectronic semiconductor component according to further embodiments.

FIG. 2C shows a schematic layout of an optoelectronic semiconductor device.

FIG. 3A to 3D show schematic vertical cross-sectional views of a workpiece during production of an optoelectronic semiconductor device according to embodiments.

FIG. 4 outlines a method according to embodiments.

### DETAILED DESCRIPTION

In the following detailed description, reference is made to the accompanying drawings, which form a part of the disclosure and in which specific exemplary embodiments are shown for purposes of illustration. In this context, directional terminology such as “top”, “bottom”, “front”, “back”, “over”, “on”, “in front”, “behind”, “leading”, “trailing”, etc. refers to the orientation of the figures just described. As the components of the exemplary embodiments may be positioned in different orientations, the directional terminology is used by way of explanation only and is in no way intended to be limiting.

The description of the exemplary embodiments is not limiting, since there are also other exemplary embodiments, and structural or logical changes may be made without departing from the scope as defined by the patent claims. In particular, elements of the exemplary embodiments described below may be combined with elements from others of the exemplary embodiments described, unless the context indicates otherwise.

The semiconductor layers described herein may in particular be monocrystalline and may, for example, be grown epitaxially. Depending on the intended use, the semiconductor may be based on a direct or an indirect semiconductor material. Examples of semiconductor materials particularly suitable for generating electromagnetic radiation include, without limitation, nitride semiconductor compounds by means of which, for example, ultraviolet, blue or longer-wave light may be generated, such as GaN, InGaN, AlN, AlGaN, AlGaInN, phosphide semiconductor compounds by means of which, for example, green or longer-wave light may be generated, such as GaAsP, AlGaInP, GaP, AlGaP, and other semiconductor materials such as AlGaAs, SiC, ZnSe, GaAs, ZnO, Ga₂O₃, diamond, hexagonal BN and combinations of the materials mentioned. The stoichiometric ratio of the ternary compounds may vary. Other examples of semiconductor materials may include silicon, silicon germanium, and germanium. In the context of the present description, the term “semiconductor” also includes organic semiconductor materials.

The term “substrate” generally includes insulating, conductive or semiconductor substrates.

The terms “lateral” and “horizontal”, as used in the present description, are intended to describe an orientation or alignment which extends essentially parallel to a first surface of a semiconductor substrate or semiconductor body. This may be the surface of a wafer or a chip (die), for example.

The horizontal direction may, for example, be in a plane perpendicular to a direction of growth when layers are grown.

The term “vertical” as used in this description is intended to describe an orientation which is essentially perpendicular to the first surface of the semiconductor substrate or semiconductor body. The vertical direction may correspond, for example, to a direction of growth when layers are grown.

To the extent used herein, the terms “have”, “include”, “comprise”, and the like are open-ended terms that indicate the presence of said elements or features, but do not exclude the presence of further elements or features. The indefinite articles and the definite articles include both the plural and the singular, unless the context clearly indicates otherwise.

In the context of this description, the term “electrically connected” means a low-ohmic electrical connection between the connected elements. The electrically connected elements need not necessarily be directly connected to one another. Further elements may be arranged between electrically connected elements.

The term “electrically connected” also encompasses tunnel contacts between the connected elements.

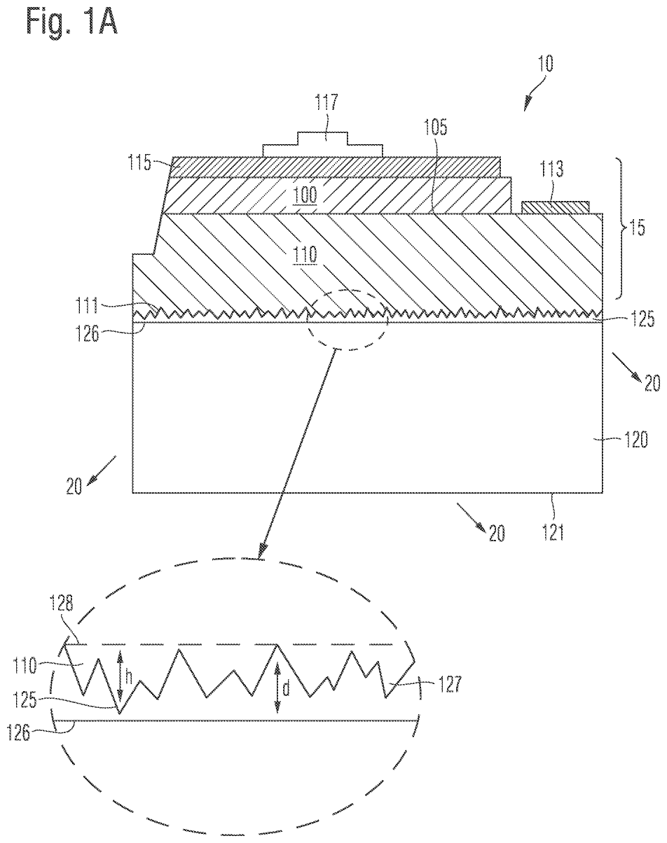

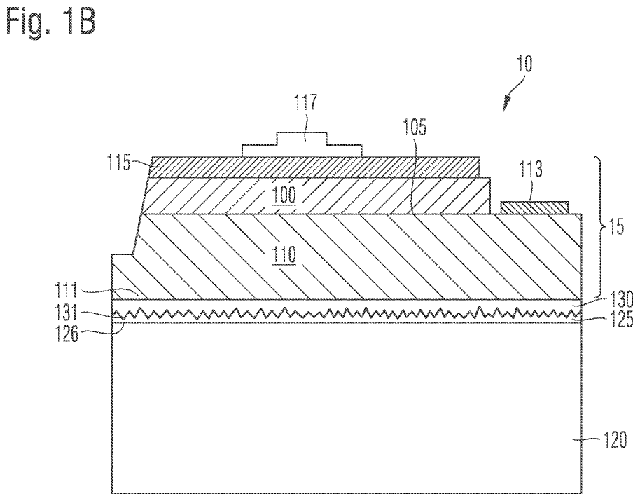

FIG. 1A shows a schematic vertical cross-sectional view of an optoelectronic component according to embodiments. The optoelectronic semiconductor component 10 comprises an optoelectronic semiconductor chip 15, a connecting material (interface material) 125 and a sapphire support 120. The connecting material 125 contains amorphous aluminum oxide and is directly adjacent to the sapphire support. The optoelectronic semiconductor chip 15 is mechanically connected to the sapphire support 120 via the connecting material 125 containing amorphous aluminum oxide.

As an example, the semiconductor chip 15 comprises a first semiconductor layer 110 of a first conductivity type, for example n-type, and a second semiconductor layer 100 of a second conductivity type, for example p-type. The first and second semiconductor layers may form a semiconductor layer stack, the first semiconductor layer 110 being arranged between the second semiconductor layer 100 and the sapphire support 120. An active zone 105 may be arranged between the first semiconductor layer 110 and the second semiconductor layer 100.

The active zone may, for example, comprise a pn junction, a double heterostructure, a single quantum well structure (SQW, single quantum well) or a multiple quantum well structure (MQW, multi quantum well) for generating radiation. The term “quantum well structure” does not imply any particular meaning here with regard to the dimensionality of the quantization. Therefore it includes, among other things, quantum wells, quantum wires and quantum dots as well as any combination of these structures.

As an example, the optoelectronic semiconductor chip 15 is embodied using thin-film technology. As will also be explained below, such thin-film semiconductor chips may be produced by separating a semiconductor layer sequence from the growth substrate after epitaxial growth. The semiconductor layer sequence is then applied to a support or carrier different from the growth substrate, for example a sapphire support. The semiconductor layer stack has a layer thickness of less than 10 μm, for example. Both the first and second semiconductor layers 110, 100 may contain GaN and may for example be constructed from a compound semiconductor material containing GaN. A layer thickness of the first semiconductor layer 110 may, for example, be greater than 3 μm. The layer thickness may, furthermore, be less than 7 μm. A layer thickness of the second semiconductor layer 100 may, for example, be less than 1 μm, for example more than 60 nm and less than 250 nm.

According to embodiments, it is provided that the optoelectronic semiconductor chip 15 is connected to the sapphire support 120 via the connecting material 125 containing amorphous aluminum oxide. That is, instead of a commonly used adhesive, amorphous aluminum oxide or a connecting material containing amorphous aluminum oxide may be used. The connecting material 125 containing amorphous aluminum oxide is directly adjacent to the first semiconductor layer 110. Due to the fact that amorphous aluminum oxide and sapphire have the same chemical composition, the connecting material 125 and the sapphire substrate 120 have the same or a similar refractive index. As a result, back reflections at the interface between the connecting material 125 and the sapphire support 120 may be avoided. As a result, the transition of light from the optoelectronic semiconductor chip into the transparent support 120 may be improved in this way. The connecting material 125 containing amorphous aluminum oxide may, for example, contain amorphous aluminum oxide or be composed of amorphous aluminum oxide. The term aluminum oxide includes Al₂O₃ and other aluminum oxides of different stoichiometric ratios. Sapphire supports used for optoelectronic semiconductor devices are made from monocrystalline aluminum oxide. The connecting material differs from the sapphire support in that it is amorphous. By applying the connecting material over the optoelectronic semiconductor chip by sputtering or other deposition processes, for example, as will be explained below, the connecting material is not crystalline but largely amorphous. By effecting the connection to the sapphire support via the connecting material containing amorphous aluminum oxide, it is possible to achieve the connection without a medium containing organic materials, for example BCB (benzocyclobutene) or silicone. Accordingly, maximum light stability is achieved.

According to embodiments, as shown in FIG. 1A, a first main surface 111 of the first semiconductor layer 110 may be roughened. The lower part of FIG. 1A shows a portion of the interface between the first semiconductor layer 110 and the connecting material 125. The roughness of the first main surface 111 of the first semiconductor layer 110 is implemented such that the roughness is more than 300 nm, for example 300 to 500 nm or more, for example up to 1.5 μm. This roughness indicates the height h of elevations 127 in relation to an imaginary baseline 128. The baseline 128 denotes the horizontal surface that is entirely covered by the first semiconductor layer 110. In other words, the first main surface 111 of the first semiconductor layer 110 may have a plurality of depressions and elevations, with the baseline 128 denoting the horizontal plane that lies in the first semiconductor layer 110 and contacts the maximum depression(s) or elevation(s). In relation to this baseline 128, the elevations have a maximum height h. A horizontal dimension of the elevations 127 may be up to ten times the specified values for the height. Due to the roughening, a location-dependent variable refraction of the emitted light may be effected. As a result, a large amount of scattering occurs at the interface between the connecting material 125 and the adjacent material, for example the first semiconductor layer 110.

The connecting material 125 containing amorphous aluminum oxide has a layer thickness d which is greater than the height h of the elevations 127. A first main surface 126 of the connecting material 125 is embodied as a planar surface. The optoelectronic semiconductor device 10 may furthermore comprise a first contact element 113, by means of which the first semiconductor layer 110 may be contacted. Furthermore, the optoelectronic semiconductor device may comprise a second contact element 117, by means of which the second semiconductor layer 100 may be contacted. As an example, a second current spreading layer 115 is provided, by means of which the second semiconductor layer 100 may be connected. The second current spreading layer 115 may, for example, be formed over a large surface area. The first contact element 113 may also extend partially into the first semiconductor layer 110. Electromagnetic radiation emitted by the optoelectronic semiconductor device 10 may be emitted, for example, via a first main surface 121 and via side surfaces of the sapphire support 120.

FIG. 1B shows a vertical cross-sectional view of the optoelectronic semiconductor component 10 according to further embodiments. In contrast to the semiconductor device shown in FIG. 1A, the first main surface 111 of the first semiconductor layer 110 is in this case formed as a planar surface. Furthermore, a dielectric intermediate layer 130 is arranged between the first semiconductor layer 110 and the connecting material 125 containing amorphous aluminum oxide. As an example, the dielectric intermediate layer 130 may be directly adjacent to the first semiconductor layer 110. Furthermore, the dielectric intermediate layer 130 may be directly adjacent to the connecting material 125 containing amorphous aluminum oxide. As an example, a first main surface 131 of the electrical intermediate layer may be patterned in a manner similar to that explained above with regard to the first semiconductor layer 110. The dielectric intermediate layer 130 comprises a transparent material. As an example, the dielectric intermediate layer may comprise a transparent polymer or any desired transparent dielectric layer, for example silicon oxide, silicon nitride or a combination of these materials.

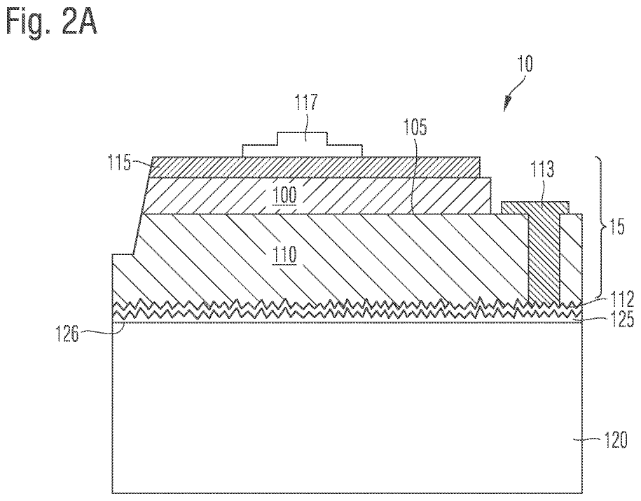

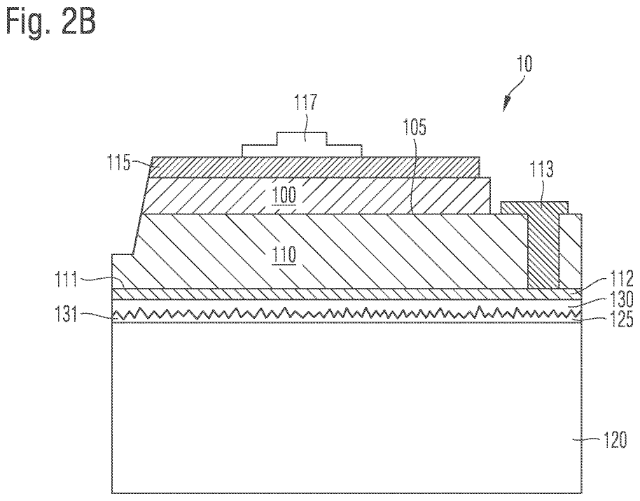

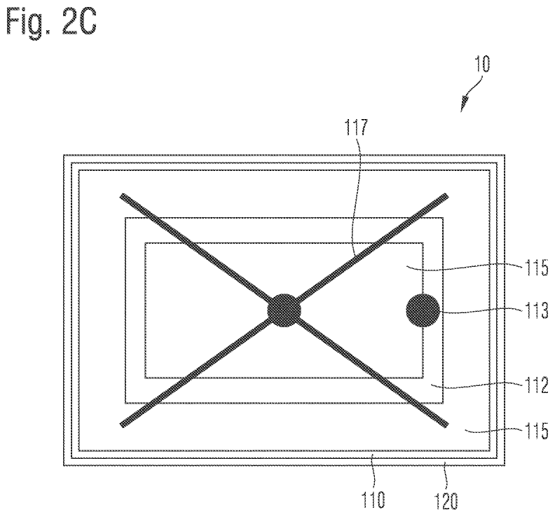

According to further embodiments, the optoelectronic semiconductor device may additionally comprise a first current spreading layer 112 which is formed in contact with the first semiconductor layer 110, as illustrated in FIG. 2A. As an example, the first current spreading layer 112 may be transparent and may be composed of a conductive oxide such as ITO (indium tin oxide), indium zinc oxide, zinc oxide and others. As an example, the first current spreading layer 112 may have a layer thickness of less than 100 nm. As an example, a layer thickness may be more than 30 nm, for example 50 or 60 nm. The first current spreading layer 112 may be formed over the entire surface area, for example. According to further embodiments, however, it may be formed over only a portion of the first main surface 111 of the first semiconductor layer 110. It may, for example, be formed symmetrically over the semiconductor component. As an example, the first current spreading layer 112 may form a ring, as will be discussed below with reference to FIG. 2C. According to further embodiments, however, it may be patterned in a different way, for example by forming conductive fingers. The layer thickness of the first current spreading layer 112 may, for example, be dimensioned such that if the first current spreading layer 112 is not formed over the entire surface area, no topography is generated within the optoelectronic semiconductor component.

According to embodiments shown in FIG. 2A, the first main surface 111 of the first semiconductor layer 110 is patterned in a way similar to FIG. 1A. A surface of the first current spreading layer 112 facing away from the first semiconductor layer 110 may likewise be roughened. As an example, the first current spreading layer 112 may be formed conformally. The connecting material 125 containing amorphous aluminum oxide is disposed adjacent to the first current spreading layer 112, as shown in FIG. 2A. A first main surface 126 of the connecting material is planar. The sapphire support 120 is adjacent to the connecting material 125 containing amorphous aluminum oxide.

According to embodiments shown in FIG. 2B, the first main surface 111 of the first semiconductor layer 110 is planar. The first current spreading layer 112 is adjacent to the first main surface 111 of the first semiconductor layer 110 and is also planar. Furthermore, a dielectric intermediate layer 130 is arranged between the first current spreading layer 112 and the connecting material 125 containing amorphous aluminum oxide. A first main surface 131 of the dielectric intermediate layer is roughened, so that the interface between the dielectric intermediate layer 131 and the connecting material 125 containing amorphous aluminum oxide is roughened. The sapphire support 120 is adjacent to the connecting material 125. As a result of the corresponding layers having a surface roughness, the coupling-out efficiency of the emitted light may be increased.

By additionally providing the first current spreading layer 112 according to embodiments, it is possible to connect the first semiconductor layer 110 over a larger surface area, compared to a case in which there is no first current spreading layer. In particular, connecting different areas of the optoelectronic semiconductor chip 15 to different potentials may be avoided. Furthermore, by providing the first current spreading layer, additional contacts for contacting the first semiconductor layer 110 may be saved. As a result, the efficiency of the device may be improved.

Due to the expense associated with the production of the first current spreading layer, a first current spreading layer between the first semiconductor layer 110 and the sapphire support 120 has previously been avoided. By applying the amorphous connecting material 125 containing amorphous aluminum oxide separately, as will be described below, the first current spreading layer 112 may be provided with insignificant additional costs.

FIG. 2C shows a schematic layout of a semiconductor device 10. The second contact element 117 may be embodied in the form of strips, for example as a cross, and extend horizontally over the semiconductor device 10. The second current spreading layer 115 may be formed over the entire surface area of the semiconductor device or semiconductor chip 15 and only those areas in which the first contact element 113 is arranged may be let blank. The first current spreading layer 112 may be patterned to form an annular region, for example. The first current spreading layer 112 may, however, also be unpatterned.

According to embodiments, since the first and second current spreading layers 112, 115 are formed on opposite sides of the semiconductor layer stack, the second and optionally the first current spreading layers 115, 112 may be formed over a large surface area.

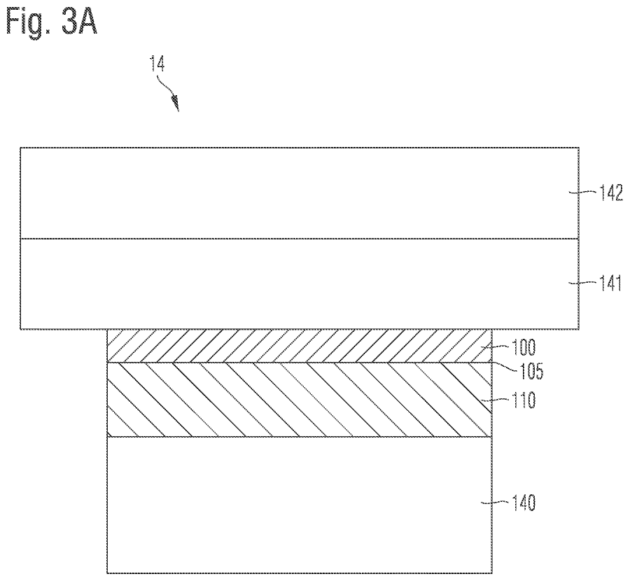

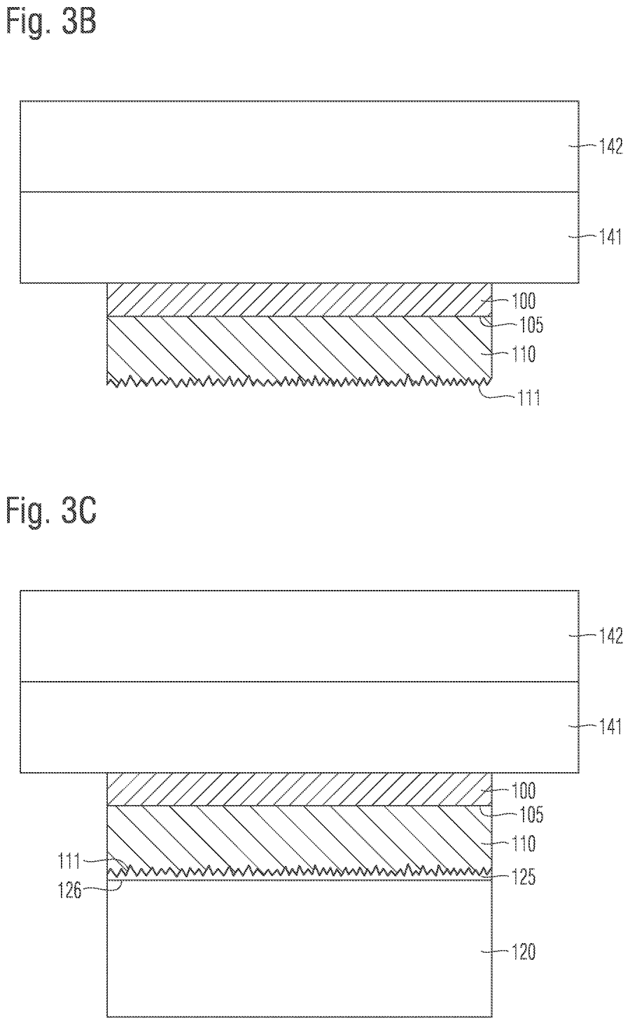

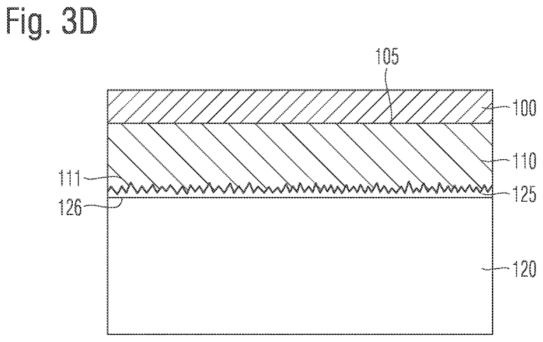

FIGS. 3A to 3D illustrate a workpiece 14 in the course of performing a method for producing the semiconductor component described. A first semiconductor layer 110 of a first conductivity type, an active zone 105, and a second semiconductor layer 100 of a second conductivity type may be grown epitaxially over a suitable growth substrate 140, for example made of GaN. The layer stack applied is then connected to an intermediate support 142 via a connecting material or an adhesive 141. FIG. 3A shows a vertical cross-sectional view of an example of a workpiece 14. Subsequently, the semiconductor layer stack is removed from the growth substrate 140, for example by a laser lift-off method. According to embodiments, a first main surface 111 of the first semiconductor layer 110 is roughened, for example by etching, for example in hot KOH.

FIG. 3B shows a vertical cross-sectional view of a workpiece after this method step. Subsequently, a connecting material 125 containing amorphous aluminum oxide may be applied onto the first main surface 111 of the first semiconductor Layer 110. As an example, the connecting material 125 containing aluminum oxide may be applied by sputtering, by a PVD method or by an ALD (“atomic layer deposition”) method. It is crucial here for the first main surface 126 of the connecting material to be extremely planar. With high planarity of the first main surface 126, free OH groups present on the surface may be connected over a large surface area with the OH groups of the sapphire substrate 120 to be applied later.

Then, a sapphire substrate 120 is contacted with the connecting material 125 containing amorphous aluminum oxide. During the connecting process, a covalent bond is created on both sides between aluminum and oxygen via the OH groups of the sapphire substrate and the connecting material 125, with elimination of water or hydrogen.

FIG. 3C shows a vertical cross-sectional view of a resulting workpiece. The intermediate support 142 and any remaining adhesive residues 141 are then removed from the exposed surface of the second semiconductor layer 100. FIG. 3D shows a vertical cross-sectional view of a resulting workpiece. Further layers may then be applied to contact the first and second semiconductor layers.

In contrast to the process flow shown in FIGS. 3A to 3D, dielectric intermediate layers and/or the first current spreading layer 112 may be applied over the first main surface 111 of the first semiconductor layer 110 after the growth substrate 140 has been removed. Furthermore, alternative patterning methods for roughening, for example, the dielectric intermediate layer may be carried out.

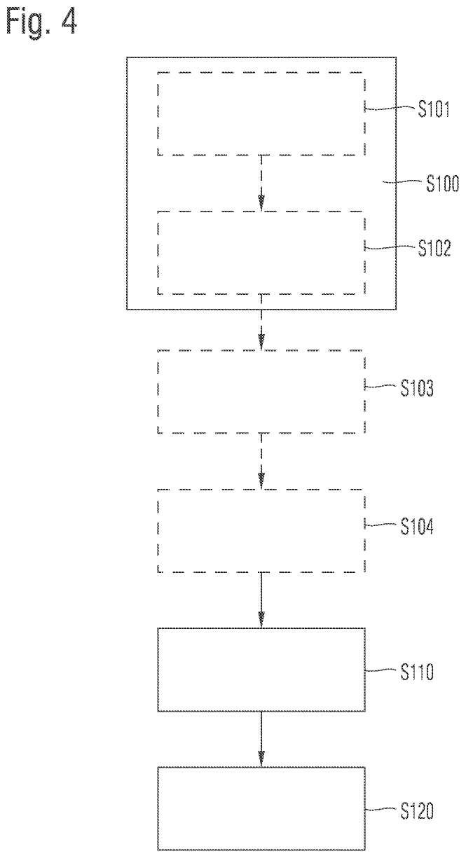

FIG. 4 outlines a method according to embodiments. A method for producing an optoelectronic semiconductor device comprises forming (S100) an optoelectronic semiconductor chip, forming (S110) a connecting material containing amorphous aluminum oxide over the optoelectronic semiconductor chip, contacting (S120) a sapphire support with the connecting material and connecting the optoelectronic semiconductor chip to the sapphire support via the connecting material.

According to embodiments, forming (S100) the optoelectronic semiconductor chip comprises forming (S101) a first semiconductor layer of a first conductivity type over a growth substrate and forming (S102) a second semiconductor layer of a second conductivity type over the first semiconductor layer. The method may furthermore comprise applying (S103) an intermediate support over the second semiconductor layer and removing (S104) the growth substrate. The connecting material containing amorphous aluminum oxide and the sapphire support are applied to one side of the first semiconductor layer.

Although specific embodiments have been illustrated and described herein, those skilled in the art will recognize that the specific embodiments shown and described may be replaced by a multiplicity of alternative and/or equivalent configurations without departing from the scope of the claims. The application is intended to cover any adaptations or variations of the specific embodiments discussed herein. Therefore, the invention is to be limited by the claims and their equivalents only.

### LIST OF REFERENCES

10 optoelectronic semiconductor device
14 workpiece
15 optoelectronic semiconductor chip
20 emitted radiation
100 second semiconductor layer
105 active zone
110 first semiconductor layer
111 first main surface of the first semiconductor layer
112 first current spreading layer
113 first contact element
115 second current spreading layer
117 second contact element
120 sapphire support
121 first main surface of the sapphire support
125 connecting material
126 first main surface of the connecting material
127 elevation
128 baseline
130 dielectric intermediate layer
131 first main surface of the dielectric intermediate layer
140 growth substrate
141 adhesive
142 intermediate support

1. An optoelectronic semiconductor device comprising:
an optoelectronic semiconductor chip;
a connecting material comprising amorphous aluminum oxide;
a sapphire support; and
a first current spreading layer;
wherein the connecting material is directly adjacent to the sapphire support and the optoelectronic semiconductor chip is connected to the sapphire support via the connecting material containing amorphous aluminum oxide; the optoelectronic semiconductor chip comprising:
a first semiconductor layer of a first conductivity type; and
a second semiconductor layer of a second conductivity type; which form a semiconductor layer stack;
wherein the first semiconductor layer is arranged between the second semiconductor layer and the sapphire support; and
wherein the first current spreading layer is arranged on a side of the first semiconductor layer facing away from the second semiconductor layer (100) and is electrically connected to the first semiconductor layer.

2. The optoelectronic semiconductor device according to claim 1, wherein a first main surface of the first semiconductor layer facing away from the second semiconductor layer is roughened and a first main surface of the connecting material facing away from the first semiconductor layer forms a planar surface.

3. The optoelectronic semiconductor device according to claim 1, wherein the connecting material is directly adjacent to the first semiconductor layer.

4. The optoelectronic semiconductor device according to claim 1, in which wherein the first current spreading layer is directly adjacent to the first semiconductor layer.

5. The optoelectronic semiconductor device according to claim 1, in which wherein a first main surface of the first semiconductor layer is roughened and a first main surface of the first current spreading layer facing away from the first semiconductor layer is roughened.

6. The optoelectronic semiconductor device according to claim 1, wherein the first current spreading layer consists of a transparent conductive material.

7. The optoelectronic semiconductor device according to claim 1, further comprising a dielectric intermediate layer on a side of the first current spreading layer facing away from the first semiconductor layer.

8. The optoelectronic semiconductor device according to claim 7, wherein a first main surface of the dielectric intermediate layer facing away from the first current spreading layer is roughened.

9. The optoelectronic semiconductor device according to claim 7, wherein the connecting material is arranged between the dielectric intermediate layer and the sapphire support.

10. The optoelectronic semiconductor device according to claim 1, wherein the first current spreading layer is formed over the entire surface area.

11. The optoelectronic semiconductor device according to claim 1, wherein the first current spreading layer is formed in a ring shape.

12. A method for producing an optoelectronic semiconductor device comprising:
forming an optoelectronic semiconductor chip;
forming a first current spreading layer;
forming a connecting material comprising amorphous aluminum oxide over the optoelectronic semiconductor chip; and
bringing a sapphire support in contact with the connecting material and connecting the optoelectronic semiconductor chip to the sapphire support via the connecting material;
wherein forming the optoelectronic semiconductor chip comprises forming a first semiconductor layer of a first conductivity type over a growth substrate and forming a second semiconductor layer of a second conductivity type over the first semiconductor layer; and
wherein the first current spreading layer is arranged on a side of the first semiconductor layer facing away from the second semiconductor layer and is electrically connected to the first semiconductor layer.

13. The method of claim 12, further comprising:
applying an intermediate support over the second semiconductor layer; and
removing the growth substrate, the connecting material containing amorphous aluminum oxide, and the sapphire support being applied to one side of the first semiconductor layer.

14. The method of claim 13, further comprising roughening a first main surface of the first semiconductor layer before applying the connecting material containing amorphous aluminum oxide.

15. The method according to claim 13, wherein the first current spreading layer is formed over the first semiconductor layer after the growth substrate has been removed.
